(19) United States
(12) Patent Application Publication
(10) Pub. No.: US 2016/0365060 A1
(43) Pub. Date: Dec. 15, 2016

(54) DISPLAY DEVICE AND PRODUCTION METHOD THEREOF

(71) Applicant: Panasonic Liquid Crystal Display Co., Ltd., Hyogo (JP)

(72) Inventors: Hiroyuki YABUKI, Osaka (JP); Toshikazu INOUE, Osaka (JP)

(21) Appl. No.: 15/248,387

(22) Filed: Aug. 26, 2016

Related U.S. Application Data
(63) Continuation of application No. PCT/JP2014/001102, filed on Feb. 28, 2014.

(51) Int. Cl. G09G 3/36; G02F 1/1343; G02F 1/1368; H01L 27/12; G02F 1/1362

(52) U.S. Cl. CPC G09G 3/3696; H01L 27/124; H01L 27/1262; G02F 1/136286; G02F 1/1368; G02F 1/13439; G09G 2310/0286; G09G 2310/066; G09G 2320/0209; G09G 2320/0233; G02F 2001/136295; G02F 2201/123

(57) ABSTRACT

A display device includes gate lines, data lines, pixel electrodes, thin film transistors each of which is disposed near each of intersection portions of the data lines and the gate lines, a slope signal generator and a voltage adjuster. The slope signal generator that generates a slope signal to generate a falling waveform of a gate signal, the slope signal including a first voltage change period and a second voltage change period, the first voltage change period being sloped from a first voltage at which the thin film transistors are put into an on state to a second voltage lower than the first voltage, the second voltage change period being sloped from the second voltage to a third voltage at which the thin film transistors are put into an off state; and the voltage adjuster that adjusts the second voltage.

### CROSS-REFERENCE TO RELATED APPLICATION

This application is a bypass continuation of international patent application PCT/JP2014/001102, filed: Feb. 28, 2014 designating the United States of America, the entire disclosure of which is incorporated herein by reference.

### TECHNICAL FIELD

The present disclosure relates to a display device and a production method thereof.

### BACKGROUND

For example, in a liquid crystal display device that is one of various display devices, an electric field generated between a pixel electrode formed in each pixel region and a common electrode is applied to liquid crystal to drive the liquid crystal, whereby a quantity of light transmitted through a region between the pixel electrode and the common electrode is adjusted to display an image. A thin film transistor is formed near an intersection portion of a gate line and a data line in each pixel region.

Conventionally, in the liquid crystal display device, there is a problem in that a pixel potential fluctuates by a jumping voltage (pull-in voltage) generated during a fall of a gate signal (scan signal). For example, the prior art discloses a technology for solving the problem (See Japanese registered Patent No. 3406508).

In the display device of the prior art, the jumping voltage is reduced by performing a slope change of a falling waveform of the gate signal supplied to a gate line.

In the technology disclosed in the prior art, it is difficult to reduce display unevenness caused by a variation in a characteristic of the thin film transistors although display unevenness caused by a signal delay on the gate line can be reduced. Specifically, for example, a variation in threshold voltage is generated by a production variation in the thin film transistors. The thin film transistor is provided in a pixel area or a gate driver, and there is a problem in that the display unevenness is generated by the variation in a characteristic of the thin film transistors.

### SUMMARY

An object of present disclosure is to provide a display device and a production method therefor, that are able to reduce the display unevenness caused by the variation in a characteristic of the thin film transistors.

In one general aspect, a display device includes gate lines, data lines, pixel electrodes, thin film transistors each of which is disposed near each of intersection portions of the data lines and the gate lines, a slope signal generator and a voltage adjuster. The slope signal generator that generates a slope signal to generate a falling waveform of a gate signal, the slope signal including a first voltage change period and a second voltage change period, the first voltage change period being sloped from a first voltage at which the thin film transistors are put into an on state to a second voltage lower than the first voltage, the second voltage change period being sloped from the second voltage to a third voltage at which the thin film transistors are put into an off state; and the voltage adjuster that adjusts the second voltage.

The above general aspect may include one or more of the following features. The voltage adjuster may adjust the second voltage in response to a characteristic of the thin film transistors.

The voltage adjuster may adjust the second voltage in each display device.

The voltage adjuster may include a variable resistor, and the second voltage may be adjusted by varying a resistance value of the variable resistor.

The voltage adjuster may include a plurality of resistors having output-side terminals connected to each other, a plurality of switches that are respectively connected to input-side terminals of the plurality of resistors, and a selector that controls switching of each of the plurality of switches.

The voltage adjuster may include a transistor. One of conductive terminals of the transistor may be grounded through a switch, another of the conductive terminals of the transistor is connected to an output terminal of the slope signal generator, and a control voltage is applied to a control terminal of the transistor.

In another general aspect, a display device production method includes forming a plurality of gate lines extending in a row direction, forming a plurality of data lines extending in a column direction, forming a plurality of pixel electrodes that are disposed according to a plurality of pixels arrayed in the row and column directions, forming a plurality of thin film transistors each of which is disposed near each of intersection portions of the plurality of data lines and the plurality of gate lines, generating a slope signal to generate a falling waveform of a gate signal, the slope signal including a first voltage change period and a second voltage change period, the first voltage change period being sloped from a first voltage at which the thin film transistors are put into an on state to a second voltage lower than the first voltage, the second voltage change period being sloped from the second voltage to a third voltage at which the thin film transistors are put into an off state; and adjusting the second voltage.

The above general aspect may include one or more of the following features. The adjusting of the second voltage may include adjusting the second voltage in a process of inspecting lighting of the display device such that display luminance becomes even in a display surface.

In the configuration of the display device of the present disclosure, the reachable voltage (second voltage) is adjusted in the falling waveform of the gate signal, so that the display unevenness caused by the variation in a characteristic of the thin film transistors can be reduced.

### BRIEF DESCRIPTION OF DRAWINGS

FIG. 1 is a plan view illustrating a schematic configuration of a liquid crystal display device according to an exemplary embodiment of the present disclosure.

FIG. 2 is a circuit diagram illustrating a configuration of the gate line driving circuit.

FIG. 3 is a circuit diagram illustrating a configuration of the slope signal generator.

FIG. 4 is a timing chart of various signals input to and output from the slope signal generator.

FIG. 5 is an enlarged waveform chart of the gate signal Vg.

FIG. 6 is a graph illustrating a relationship between the reachable voltage Vgm and the jumping voltage on the positive electrode side.

FIG. 7 is a graph illustrating a relationship between the reachable voltage Vgm and the jumping voltage on the negative electrode side.

FIG. 8 is a graph illustrating a relationship between the reachable voltage Vgm and a difference (effective voltage difference) between an effective voltage without slope change of the falling waveform of the gate signal Vg and an effective voltage with the slope change.

FIG. 9A is a graph illustrating a relationship between the reachable voltage Vgm and the difference (effective voltage difference) between the effective voltage without slope change of the falling waveform of the gate signal Vg and the effective voltage with the slope change.

FIG. 9B is an enlarged view of a part of FIG. 9A.

FIG. 10 is a circuit diagram illustrating another configuration of the slope signal generator.

FIG. 11 is a circuit diagram illustrating another configuration of the slope signal generator.

FIG. 12 is a circuit diagram illustrating another configuration of the slope signal generator.

FIGS. 13A and 13B are graphs illustrating a relationship between the reachable voltage Vgm and the luminance difference.

FIG. 14 is a graph illustrating a relationship between the reachable voltage Vgm and the luminance difference in the liquid crystal panel in which the display area is horizontally divided.

### DETAILED DESCRIPTION

Hereinafter, exemplary embodiments of the present disclosure will be described with reference to the drawings. A liquid crystal display device is described below by way of example. However, a display device according to the present disclosure is not limited to the liquid crystal display device, but may be an organic EL display device and the like.

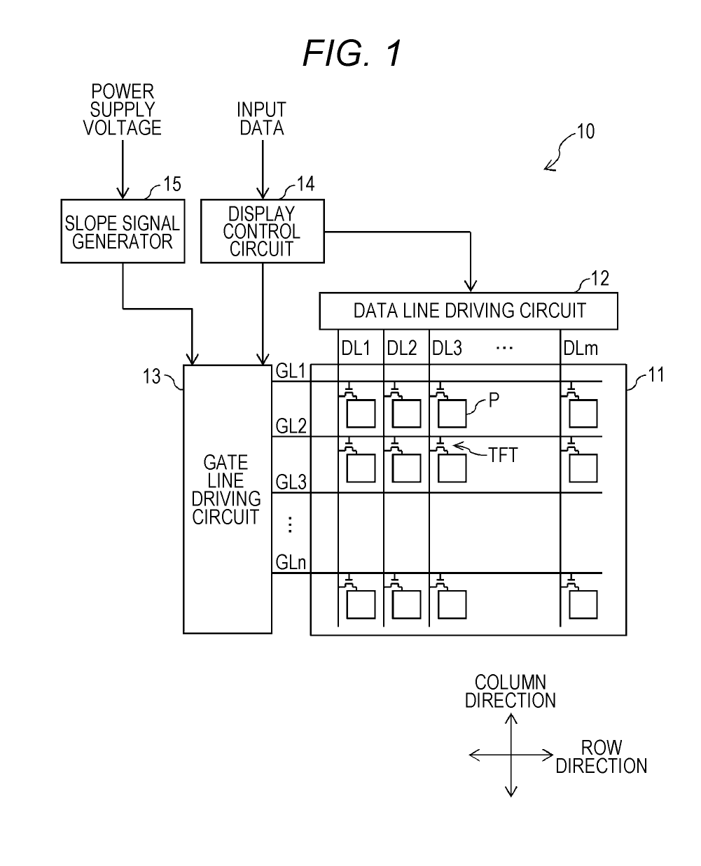

FIG. 1 is a plan view illustrating a schematic configuration of a liquid crystal display device according to an exemplary embodiment of the present disclosure. A liquid crystal display device 10 includes a liquid crystal panel 11, a data line driving circuit 12, a gate line driving circuit 13, a display control circuit 14, and a slope signal generator 15.

A plurality of data lines DL1, DL2, DL3, . . . , and DLm connected to the data line driving circuit 12 and a plurality of gate lines GL1, GL2, GL3, . . . , and GLn connected to the gate line driving circuit 13 are provided in the liquid crystal panel 11, and a thin film transistor TFT is provided at each intersection portion of the data lines DL and gate lines GL.

In the liquid crystal panel 11, a plurality of pixels P are arranged into a matrix shape (a row direction and a column direction) according to the intersection portions of the data lines DL and gate lines GL. Although not illustrated, the liquid crystal panel 11 includes a thin film transistor substrate (TFT substrate), a color filter substrate (CF substrate), a liquid crystal layer sandwiched between the TFT substrate and the CF substrate, a pixel electrode provided in the TFT substrate, and a common electrode provided in the CF substrate. The common electrode may be provided in the TFT substrate. A known configuration can be applied in the liquid crystal panel 11.

The display control circuit 14 controls the data line driving circuit 12 and gate line driving circuit 13. Specifically, based on input data (such as a synchronous signal and a video signal) input from an outside, the display control circuit 14 outputs a control signal controlling timing to drive the data line driving circuit 12 and the gate line driving circuit 13 and image data corresponding to an image displayed in an image display area of the liquid crystal panel 11.

Based on a power supply voltage input from the outside and a control signal (later-control signal Stc), the slope signal generator 15 generates a signal (a later-described gate slope signal Vgs) generating a gate signal, and outputs the signal to the gate line driving circuit 13. The slope signal generator 15 may be provided in the gate line driving circuit 13.

The data line driving circuit 12 outputs a data voltage to each data line DL based on the control signal input from the display control circuit 14 and the image data.

Based on the control signal input from the display control circuit 14 and the gate slope signal input from the slope signal generator 15, the gate line driving circuit 13 generates a gate signal, and outputs the gate signal to each gate line GL.

In the liquid crystal panel 11, when the thin film transistor TFT connected to the gate line GL is turned on by the gate signal (gate-on voltage), the data voltage is applied from the data line DL to a pixel electrode of the pixel P connected to the thin film transistor TFT. The liquid crystal is driven by an electric field generated by a difference between the data voltage applied to the pixel electrode and a common voltage applied to the common electrode, whereby light transmission is controlled to display the image.

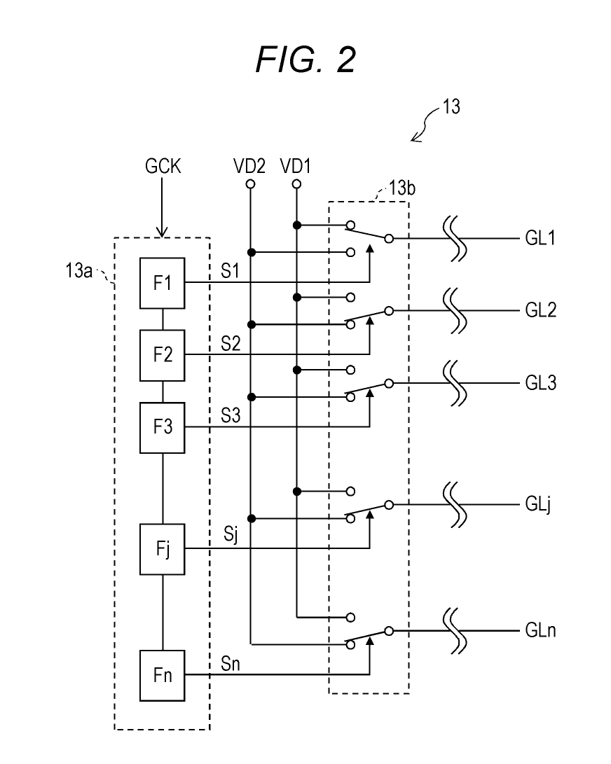

FIG. 2 is a circuit diagram illustrating a configuration of the gate line driving circuit 13. The gate line driving circuit 13 includes a shift register 13a including a plurality of series-connected flip-flops F1, F2, F3, . . . , and Fn and a selector switch 13b that is switched in response to switching signals S1, S2, S3, . . . , and Sn output from each flip-flop F. A clock signal GCK output from the display control circuit 14 is input to the shift register 13a. A gate slope signal Vgs generated by the slope signal generator 15 is input to an input terminal VD1 of each selector switch 13b, and a signal (gate-off voltage Vgl) putting the thin film transistor TFT into an off state is input to an input terminal VD2. The gate slope signal Vgs includes a period of a signal (gate-on voltage Vgh) having a level sufficient to put the thin film transistor TFT into the on state. Common terminals of the selector switches 13b are connected to the gate lines GL1, GL2, GL3, . . . , and GLn.

For example, the shift register 13a takes in a gate start pulse in synchronization with the clock signal GCK when the clock signal GCK rises, and the shift register 13a sets a leading bit to 1 when the clock signal GCK falls From then on, the shift register 13a shifts 1 downward every time the clock signal GCK falls Each bit of the shift register 13a is input to each selector switch 13b as a switching signal S. When the shift register 13a has a bit logical value of 1, the input terminal VD1 is selected, and the gate line GL is connected to the input terminal VD1. When the shift register 13a has a bit logical value of 0, the input terminal VD2 is selected, and the gate line GL is connected to the input terminal VD2. The gate line driving circuit 13 is not limited to the configuration in FIG. 2; however, a known configuration can be used.

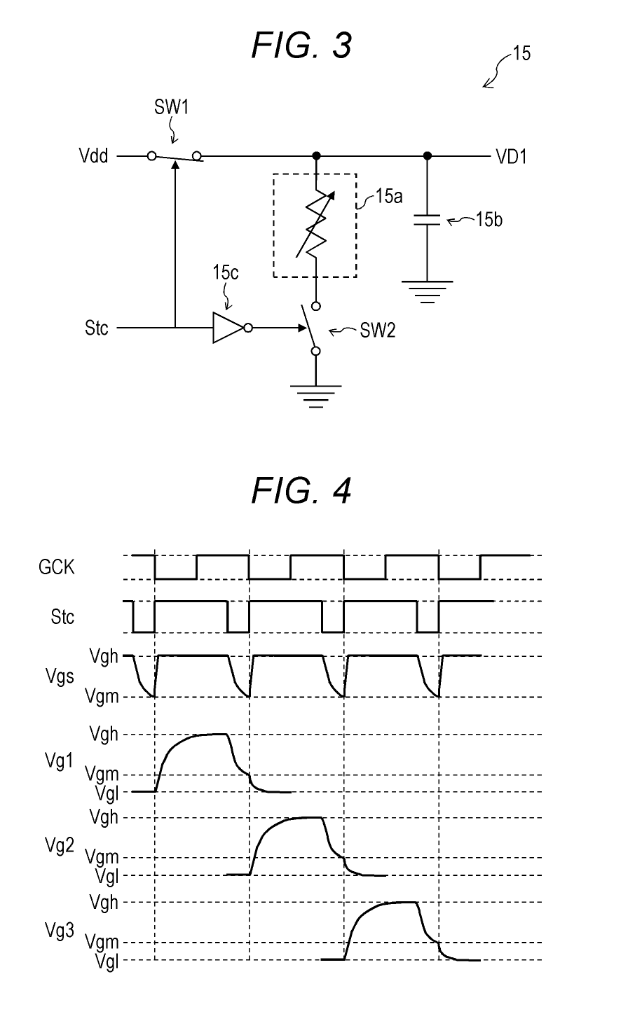

FIG. 3 is a circuit diagram illustrating a configuration of the slope signal generator 15. The slope signal generator 15 includes a variable resistor 15a (voltage adjuster), a capacitor 15b, an inverter 15c, and switches SW1 and SW2. One of terminals of the switch SW1 is connected to an input terminal of the slope signal generator 15, and a voltage Vdd (power supply voltage) is input to the switch SW1. The voltage Vdd is a DC voltage having a level Vgh sufficient to put the thin film transistor TFT into the on state. The other terminal of the switch SW1 is connected to one of the ends of the variable resistor 15a, one of the ends of the capacitor 15b, and an output terminal of the slope signal generator 15. The other end of the variable resistor 15a is grounded through the switch SW2. The other end of the capacitor 15b is grounded.

A control signal Stc performs switching control of the switch SW1 and switching control of the switch SW2 through the inverter 15c. When the control signal Stc is at a high level, the switch SW1 enters the on state because the high level is supplied, and the switch SW2 enters an off state because a low level is supplied through the inverter 15c. On the other hand, when the control signal Stc is at a low level, the switch SW1 enters the off state because the low level is supplied, and the switch SW2 enters the on state because a high level is supplied through the inverter 15c.

A gate slope signal Vgs generated by the slope signal generator 15 is input to the input terminal VD1 of the gate line driving circuit 13 in FIG. 2.

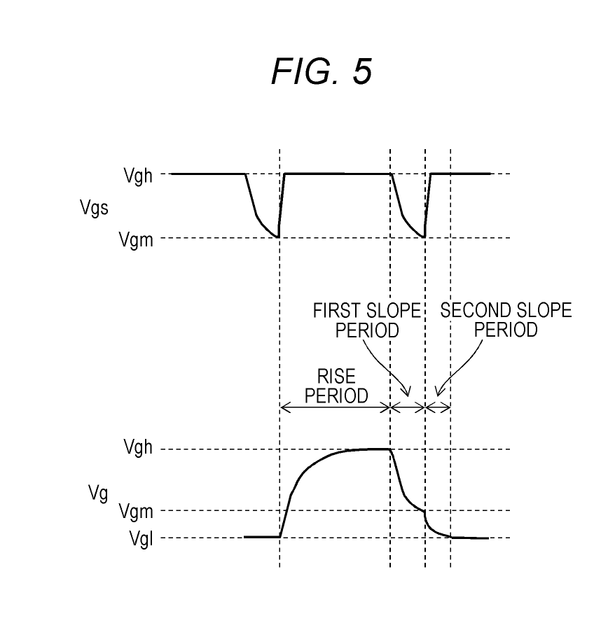

FIG. 4 is a timing chart of various signals input to and output from the slope signal generator 15. FIG. 4 also illustrates gate signals Vg1, Vg2, and Vg3 output from the gate line driving circuit 13 to the gate lines GL1, GL2, and GL3.

The control signal Stc is a timing signal controlling the falling period of the gate signal, and the control signal Stc is synchronized with the clock signal GCK.

In the period during which the control signal Stc is at the high level, because the switch SW1 enters the on state while the switch SW2 enters the off state, the gate slope signal Vgs is input to the input terminal VD1 of the gate line driving circuit 13 as a voltage level Vgh (Vdd). On the other hand, in the period during which the control signal Stc is at the low level, because the switch SW1 enters the off state while the switch SW2 enters the on state, charges accumulated in the capacitor 15b are discharged through the variable resistor 15a, and the voltage level is gradually lowered. Therefore, the gate slope signal Vgs becomes a sloped falling waveform. Then, when the control signal Stc rises to the high level, the gate slope signal Vgs rises to the voltage level Vgh from the voltage level Vgm again. Resultantly, as illustrated in FIG. 4, the gate slope signal Vgs becomes a sawtooth shape in which the high level is Vgh while the low level is Vgm.

When the gate slope signal Vgs generated by the slope signal generator 15 is input to the input terminal VD1 of the gate line driving circuit 13, the gate signal Vg on which the falling waveform is sloped as illustrated in FIG. 4 is output to the gate line GL based on operations of the shift register 13a and the selector switch 13b.

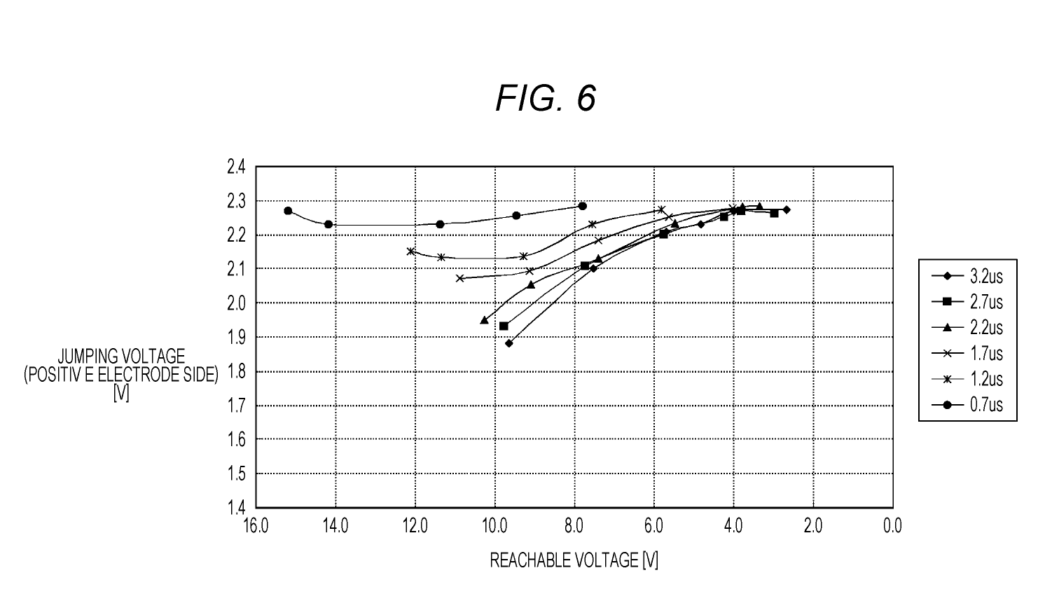

FIG. 5 is an enlarged waveform chart of the gate signal Vg. As illustrated in FIG. 5, the gate signal Vg has a waveform including a rise period in which the voltage level rises from Vgl to Vgh (a first voltage), a first slope period (first voltage change period) corresponding to the gate slope signal Vgs in which the voltage level is sloped from Vgh to Vgm (a second voltage, namely, the reachable voltage), and a second slope period (second voltage change period) in which the voltage level is sloped from Vgm to Vgl (third voltage). In the configuration of FIG. 5, the falling waveform of the gate signal Vg changes in a sloped manner, so that the fluctuation in pixel potential caused by the jumping voltage (pull-in voltage) can be suppressed.

An influence of the voltage level Vgm (the reachable voltage, namely, an intermediate voltage) in the gate signal Vg on display quality will be discussed.

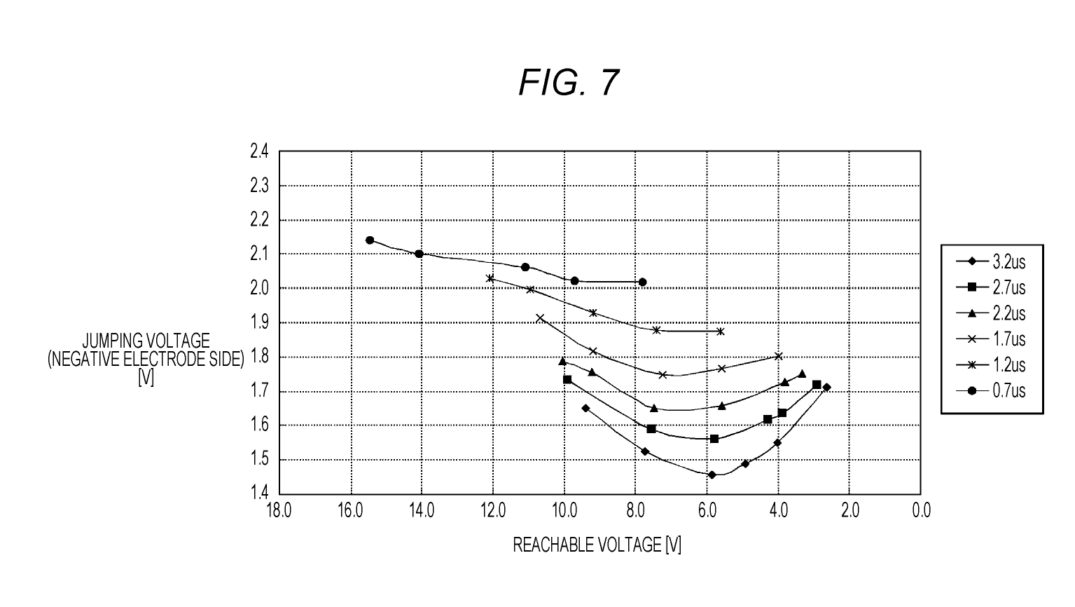

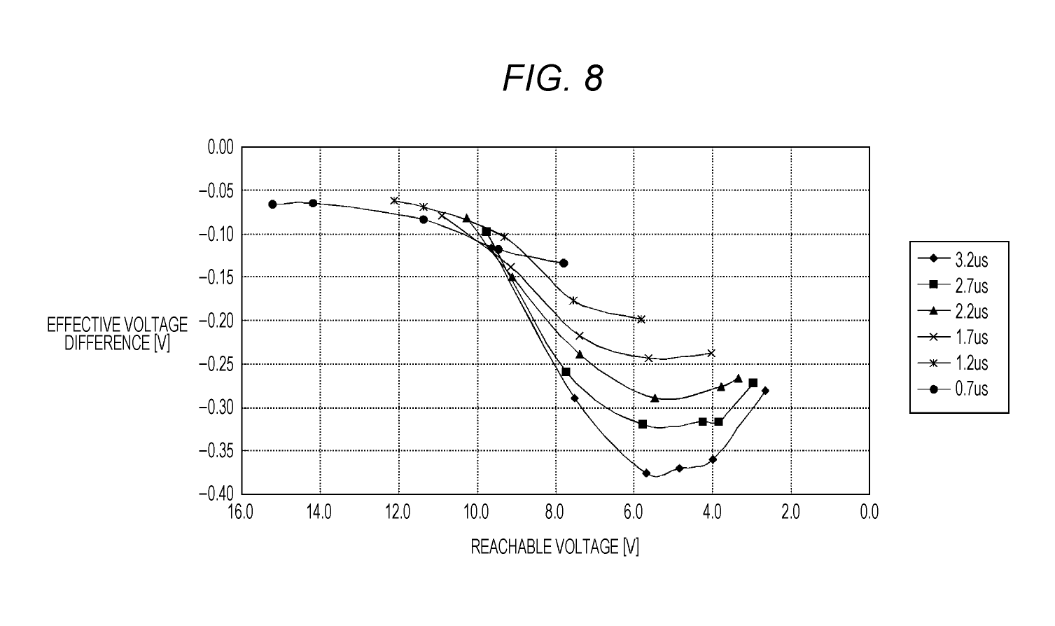

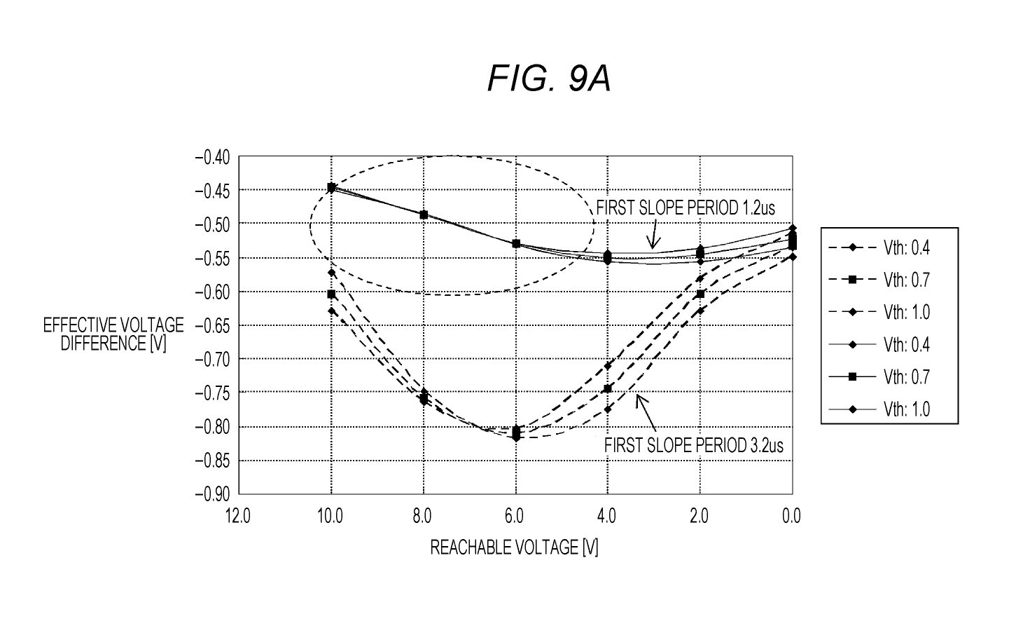

FIG. 6 is a graph illustrating a relationship between the reachable voltage Vgm and the jumping voltage on the positive electrode side, and FIG. 7 is a graph illustrating a relationship between the reachable voltage Vgm and the jumping voltage on the negative electrode side. FIG. 8 is a graph illustrating a relationship between the reachable voltage Vgm and a difference (effective voltage difference) between an effective voltage without slope change of the falling waveform of the gate signal Vg and an effective voltage with the slope change. The effective voltage indicates a difference between the jumping voltage on the positive electrode side in FIG. 6 and the jumping voltage on the negative electrode side in FIG. 7. FIGS. 6 to 8 illustrate a plurality of cases in which the first slope period varies.

As can be seen from FIG. 6, on the positive electrode side, the jumping voltage increases as reachable voltage Vgm decreases, and the jumping voltage increases as first slope period decreases. As can be seen from FIG. 7, on the negative electrode side, the jumping voltage decreases as reachable voltage Vgm increases, within a predetermined range (for example, 0 V to 6 V). On the other hand, out of the predetermined range, the jumping voltage increases as reachable voltage Vgm increases, and the jumping voltage increases as first slope period increases.

As illustrated in FIG. 8, the change in effective voltage difference is similar to the change in jumping voltage on the negative electrode side in FIG. 7. As can be seen from FIG. 8, when the reachable voltage Vgm falls within a predetermined range (for example, 4 V to 6 V), the change in effective voltage difference decreases irrespective of the first slope period.

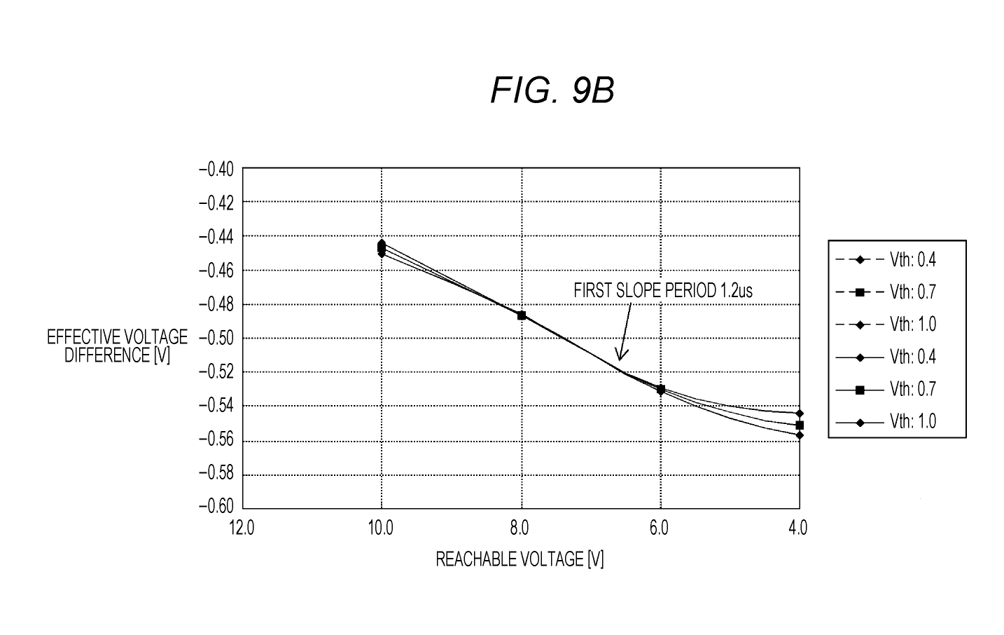

Generally, in the thin film transistor TFT, a variation in threshold voltage is generated in a surface of the liquid crystal panel 11 due to the production variation. In consideration of this characteristic of the thin film transistor TFT, it is thought that the jumping voltage varies to generate the luminance unevenness because a variation in reachable voltage Vgm is also generated due to the variation in threshold voltage between the thin film transistors TFT. FIG. 9A is a graph illustrating a relationship between the reachable voltage Vgm and the difference (effective voltage difference) between the effective voltage without slope change of the falling waveform of the gate signal Vg and the effective voltage with the slope change according to a plurality of different threshold voltages Vth. FIG. 9B is an enlarged view of a part (surrounded by a dotted line) of FIG. 9A. As can be seen from FIGS. 9A and 9B, the variation in effective voltage difference is generated according to the variation in threshold voltage Vth. For example, when the reachable voltage Vgm is set to a range of 2.0 V to 4.0 V or a range of 10.0 V or more, the effective voltage difference generated by the variation in threshold voltage Vth varies to generate the luminance unevenness. On the other hand, when the reachable voltage Vgm is set to a range of 7.0 V to 9.0 V, the effective voltage difference generated by the variation in threshold voltage Vth can be set to an identical value to reduce the luminance unevenness.

The effective voltage difference generated by the variation in threshold voltage Vth can be adjusted by adjusting the reachable voltage Vgm. From the viewpoint of “ease of adjustment” of the reachable voltage Vgm, desirably the effective voltage difference changes gently with respect to the reachable voltage Vgm like the case of the first slope period of 1.2 μs in FIG. 9A. At the same time, because of a narrowed adjustment width of the effective voltage difference, it is necessary to provide the first slope period having a proper length. That is, when the first slope period is excessively lengthened, a writing period is shortened and the display quality is degraded due to shortage of writing.

A method for setting the reachable voltage Vgm will be described below. As illustrated in FIG. 3, the reachable voltage Vgm corresponds to the low-level voltage of the gate slope signal Vgs. The reachable voltage Vgm is set by setting a resistance value of the variable resistor 15a of the slope signal generator 15 to a desired value. For example, in a process of inspecting lighting of the liquid crystal panel 11, the resistance value of the variable resistor 15a is adjusted to set the optimum reachable voltage Vgm such that the display luminance becomes even. For example, the reachable voltage Vgm can be set large by increasing the resistance value of the variable resistor 15a, and the reachable voltage Vgm can be set small by decreasing the resistance value of the variable resistor 15a. Thus, in each liquid crystal panel 11, the optimum reachable voltage Vgm is set by adjusting the resistance value of the variable resistor 15a, which allows the variation to be suppressed in the display surface.

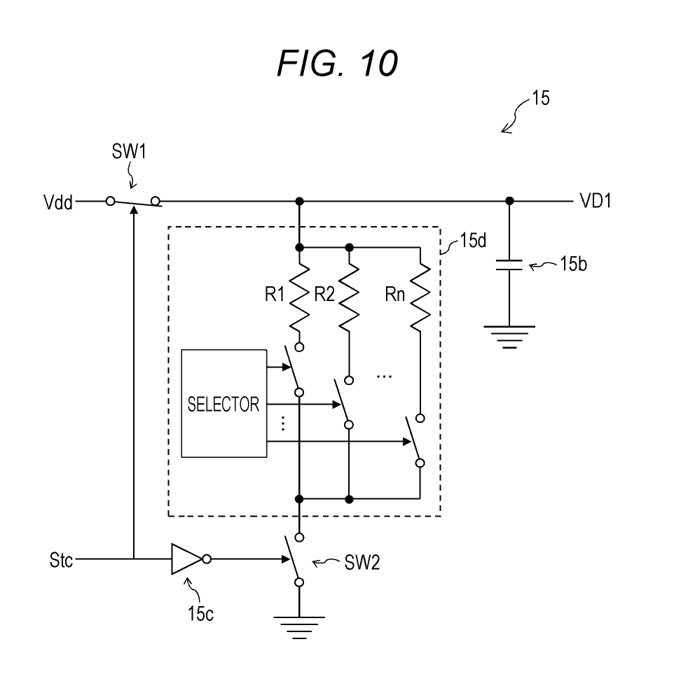

The slope signal generator 15 is not limited to the configuration in FIG. 3. FIG. 10 is a circuit diagram illustrating another configuration of the slope signal generator 15. In the slope signal generator 15 of FIG. 10, the variable resistor 15a in FIG. 3 is replaced with a resistance selector 15d (voltage adjuster), and the other elements are identical to those of the slope signal generator 15 in FIG. 3. The resistance selector 15d includes a plurality of resistors R1, R2, . . . , and Rn, a switch that is connected to one terminal of each resistor, and a selector that controls the switching of each switch. The resistance selector 15d selects one resistor according to a setting value of the selector. Therefore, the resistance value of the resistor connected to the output terminal of the slope signal generator 15 can be adjusted in a digital manner. In each liquid crystal panel 11, the resistance value and the reachable voltage Vgm are set by adjusting the value of the selector, which allows the variation to be suppressed in the display surface.

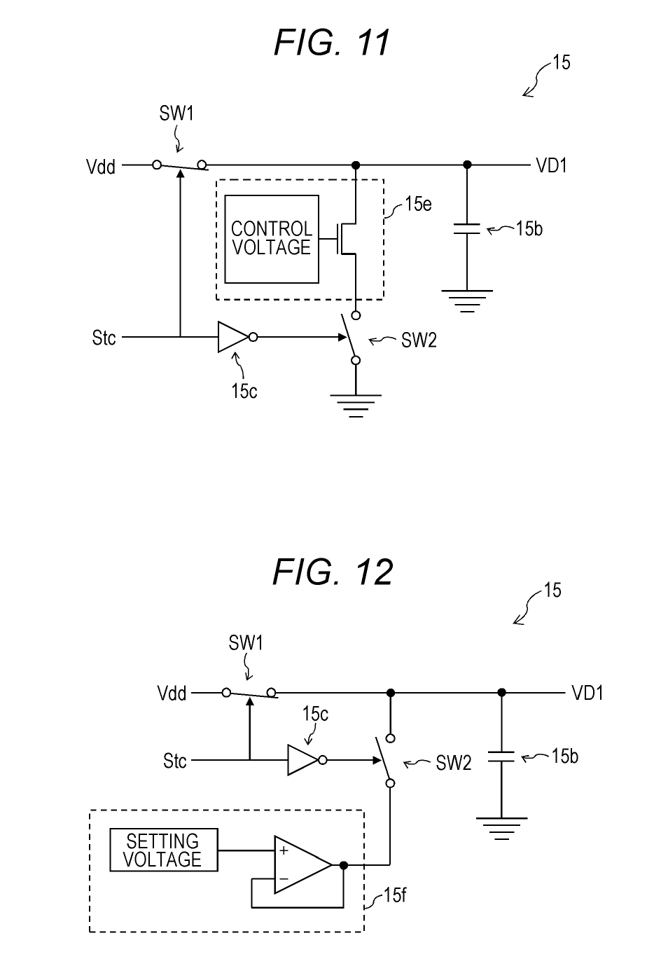

FIG. 11 is a circuit diagram illustrating still another configuration of the slope signal generator 15. In the slope signal generator 15 of FIG. 11, the variable resistor 15a in FIG. 3 is replaced with a voltage controller 15e (voltage adjuster), and the other elements are identical to those of the slope signal generator 15 in FIG. 3. The voltage controller 15e includes a transistor. A control voltage is applied to a control terminal of the transistor, one of conductive terminals is connected to one of the terminals of the switch SW1 and an output terminal of the slope signal generator 15, and the other conductive terminal is grounded through the switch SW2. In the configuration of FIG. 11, the reachable voltage Vgm can be adjusted by adjusting the control voltage applied to the transistor. Therefore, in each liquid crystal panel 11, the optimum reachable voltage Vgm is set by adjusting the control voltage, which allows the variation to be suppressed in the display surface.

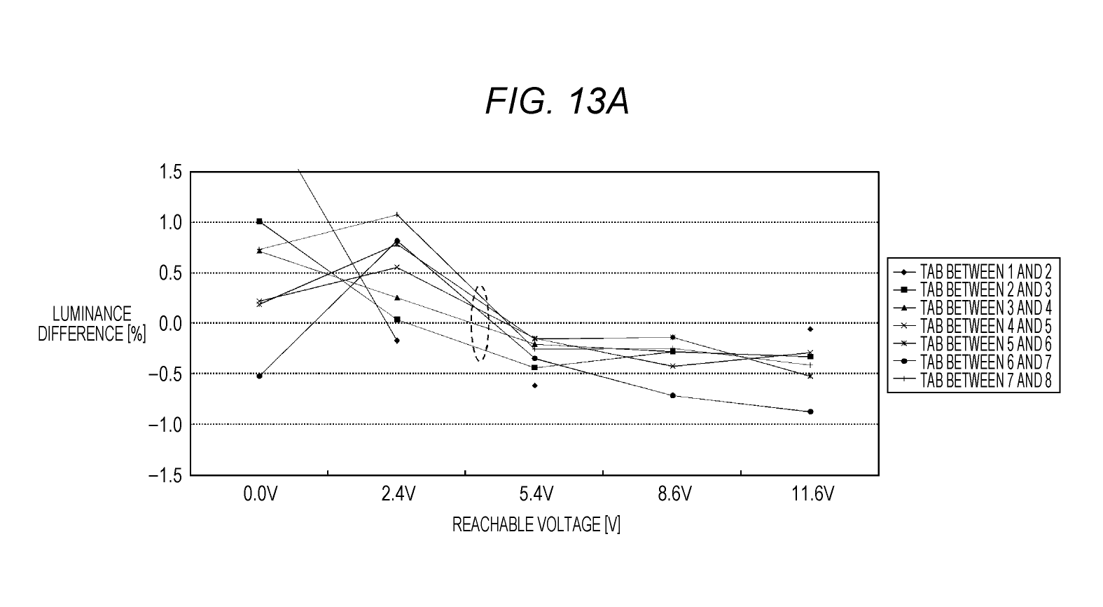

FIG. 12 is a circuit diagram illustrating yet another configuration of the slope signal generator 15. In the slope signal generator 15 of FIG. 12, the variable resistor 15a in FIG. 3 is eliminated, a voltage setting unit 15f (voltage adjuster) is connected to one of the terminals of the switch SW2, and the other elements are identical to those of the slope signal generator 15 in FIG. 3. The voltage setting unit 15f includes an operational amplifier. A setting voltage is input to one of input terminals of the operational amplifier. Therefore, the reachable voltage Vgm can be adjusted in response to the setting voltage. Therefore, in each liquid crystal panel 11, the optimum reachable voltage Vgm is set by adjusting the setting voltage, which allows the variation to be suppressed in the display surface.

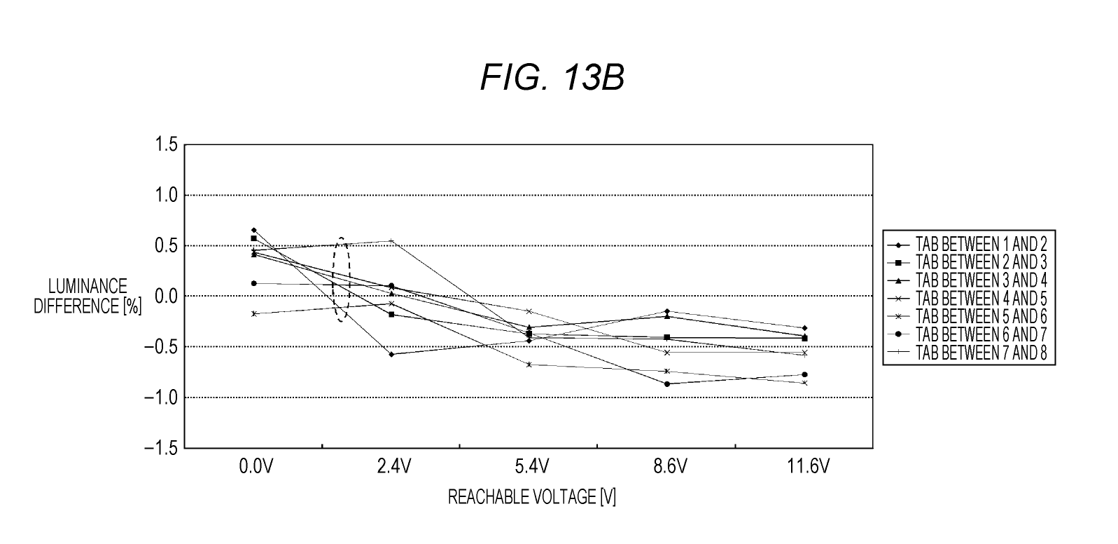

An example in which the display characteristic depends on the liquid crystal panel will be described below. FIGS. 13A and 13B are graphs illustrating a relationship between the reachable voltage Vgm and the luminance difference. FIG. 13A illustrates a liquid crystal panel A, and a FIG. 13B illustrates a liquid crystal panel B. In FIG. 13A, an area is divided in each of a plurality of gate drivers IC, and the luminance difference at a boundary (between tabs) of the areas adjacent to each other is measured in response to the reachable voltage Vgm. A luminance variation decreases in the surface of the liquid crystal panel as the luminance difference between the tabs comes close to 0%. Therefore, preferably the reachable voltage Vgm is set to a value in which the luminance difference between the tabs converges on 0%. For example, the reachable voltage Vgm is set to 4.2 V in the liquid crystal panel A, and the reachable voltage Vgm is set to 1.5 V in the liquid crystal panel B.

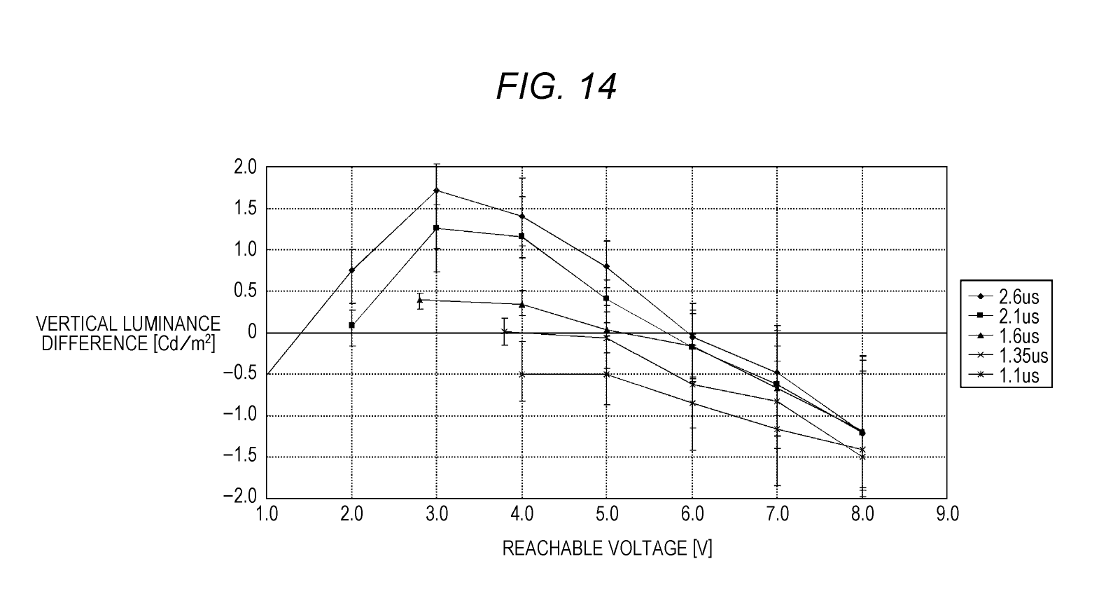

The display characteristic of the liquid crystal panel in which the display area is divided will be described below. FIG. 14 is a graph illustrating a relationship between the reachable voltage Vgm and the luminance difference in the liquid crystal panel in which the display area is vertically divided. FIG. 14 illustrates a relationship between the reachable voltage Vgm and the luminance difference according to a plurality of different first slope periods. In the liquid crystal panel, the data line DL is separated in a center of the display area, the upper data line DL is connected to a data line driving circuit provided on the upper side, the lower data line DL is connected to a data line driving circuit provided on the lower side, and the image is displayed by vertical division driving. FIG. 14 illustrates a plurality of cases in which the first slope period varies. As can be seen from FIG. 14, for example, for the first slope period of 1.35 μs, the luminance difference between the upper and lower display areas is eliminated by setting the reachable voltage Vgm to 4 V to 5 V, and the variation in luminance difference decreases even if the reachable voltage Vgm fluctuates.

Although exemplary embodiments of the present disclosure are described above, the present disclosure is not limited to these exemplary embodiments. It is noted that exemplary embodiments properly changed from the exemplary embodiments described above by those skilled in the art without departing from the scope of the present disclosure are included in the present disclosure.

What is claimed is:

1. A display device comprising:
a plurality of gate lines extending in a row direction;
a plurality of data lines extending in a column direction;
a plurality of pixel electrodes that are disposed according to a plurality of pixels arrayed in the row and column directions;
a plurality of thin film transistors each of which is disposed near each of intersection portions of the plurality of data lines and the plurality of gate lines;
a slope signal generator that generates a slope signal to generate a falling waveform of a gate signal, the slope signal including a first voltage change period and a second voltage change period, the first voltage change period being sloped from a first voltage at which the thin film transistors are put into an on state to a second voltage lower than the first voltage, the second voltage change period being sloped from the second voltage to a third voltage at which the thin film transistors are put into an off state; and
a voltage adjuster that adjusts the second voltage.

2. The display device according to claim 1, wherein the voltage adjuster adjusts the second voltage in response to a characteristic of the thin film transistors.

3. The display device according to claim 1, wherein the voltage adjuster adjusts the second voltage in each display device.

4. The display device according to claim 1, wherein the voltage adjuster includes a variable resistor, and
the second voltage is adjusted by varying a resistance value of the variable resistor.

5. The display device according to claim 1, wherein the voltage adjuster includes a plurality of resistors having output-side terminals connected to each other, a plurality of switches that are respectively connected to input-side terminals of the plurality of resistors, and a selector that controls switching of each of the plurality of switches.

6. The display device according to claim 1, wherein the voltage adjuster includes a transistor, and
one of conductive terminals of the transistor is grounded through a switch, another of the conductive terminals of the transistor is connected to an output terminal of the slope signal generator, and a control voltage is applied to a control terminal of the transistor.

7. A display device production method comprising:
forming a plurality of gate lines extending in a row direction;
forming a plurality of data lines extending in a column direction;
forming a plurality of pixel electrodes that are disposed according to a plurality of pixels arrayed in the row and column directions;
forming a plurality of thin film transistors each of which is disposed near each of intersection portions of the plurality of data lines and the plurality of gate lines;
generating a slope signal to generate a falling waveform of a gate signal, the slope signal including a first voltage change period and a second voltage change period, the first voltage change period being sloped from a first voltage at which the thin film transistors are put into an on state to a second voltage lower than the first voltage, the second voltage change period being sloped from the second voltage to a third voltage at which the thin film transistors are put into an off state; and
adjusting the second voltage.

8. The display device production method according to claim 7, wherein the adjusting of the second voltage comprises adjusting the second voltage in a process of inspecting lighting of the display device such that display luminance becomes even in a display surface.
